(19) United States
(12) Patent Application Publication
(10) Pub. No.: US 2023/0197409 A1
(43) Pub. Date: Jun. 22, 2023

(54) ANTENNA ASSEMBLY AND PLASMA PROCESSING EQUIPMENT INCLUDING SAME

(71) Applicant: SEMES CO., LTD., Cheonan-si (KR)

(72) Inventors: Hyun Jin KIM, Daegu (KR); GALSTYAN OGSEN, Cheonan-si (KR); Jung Hwan LEE, Ansan-si (KR); Dong Jun PARK, Osan-si (KR); Sang Hyeok AHN, Cheonan-si (KR)

(73) Assignee: SEMES CO., LTD., Cheonan-si (KR)

(21) Appl. No.: 18/083,555

(22) Filed: Dec. 18, 2022

(30) Foreign Application Priority Data
Dec. 20, 2021 (KR) 10-2021-0182544

(51) Int. Cl. H01J 37/32

(52) U.S. Cl. CPC H01J 37/3211; H01J 37/32183; H01J 2237/334

(57) ABSTRACT

An antenna assembly, which is capable of controlling widely an etching rate in a plasma treatment process, and a plasma processing equipment including the same are provided. The antenna assembly provided to generate plasma includes a feeding line to which a radio frequency (RF) signal may be applied, and a coil member including a plurality of unit coils coupled to the feeding line and spaced apart from each other in a vertical direction at a predetermined gap.

### CROSS REFERENCE TO RELATED APPLICATION

The present application claims priority to Korean Patent Application No. 10–2021–0182544, filed Dec. 20, 2021, the entire contents of which is incorporated herein for all purposes by this reference.

### BACKGROUND OF THE INVENTION

### Field of the Invention

The present disclosure relates generally to an antenna assembly and a plasma processing equipment including the same.

### Description of the Related Art

A semiconductor (or display) manufacturing process is a process for manufacturing a semiconductor device on a substrate (e.g., wafer), and for example, includes exposing, depositing, etching, ion implanting, cleaning, etc. In order to perform each manufacturing process, semiconductor manufacturing facilities performing each process are provided in a clean room of a semiconductor manufacturing plant, and a process is performed on a substrate inserted into the semiconductor manufacturing facilities.

In the substrate manufacturing process, processes using plasma, for example, etching, depositing, etc. are widely used. A plasma processing apparatus performing a plasma treatment process may perform the process while changing various process conditions such as process gas, temperature, pressure, a frequency of radio frequency (RF) signal for generating plasma, power, etc.

As a method for forming plasma to perform the plasma treatment process, capacitively coupled plasma (CCP) and inductively coupled plasma (ICP) exist, and the CCP generates plasma by using a capacitor electric field, and the ICP generates plasma by using an induced electric field. Specifically, the ICP can generate plasma having 10 times higher density than the CCP and maintains a higher temperature than the CCP. Due to the plasma characteristics, the ICP can be used in etching, depositing, and cleaning processes with high densities of neutral active species and ions.

Recently, as an area of the semiconductor substrate (wafer) is enlarged, the manufacturing facility for plasma processing is also increasing in area. In an ICP plasma source, a large area of an antenna to form the induced electric field in a chamber is also in progress, and at the same time, an improvement technique for plasma uniformity deterioration due to increase in antenna area is also being studied.

Furthermore, in a semiconductor stack structure such as 3D NAND flash, as a stacked height is increased, more neutral active species and higher ion density are required to improve the etching rate, thereby increasing the power applied to the antenna. Due to the high power, there is a problem in that it is difficult to control the uniformity in a radial direction in an antenna assembly including an inner coil and an outer coil. According to a current ratio (CR) applied to the inner coil and the outer coil, it is confirmed that the etching rate at a center portion of the wafer changes greatly, but the etch rate at an outer portion of the wafer does not change significantly, so a technique capable of controlling the etching rate more extensively in the outer portion of the wafer is required.

### SUMMARY OF THE INVENTION

Accordingly, an embodiment of the present disclosure provides an antenna assembly and a plasma processing equipment including the same, the antenna assembly being configured to control an etching rate more widely in a plasma treatment process.

The technical problem of the present disclosure is not limited to the above mention, and other problem not mentioned will be clearly understood by those skilled in the art from the description below.

According to one aspect of the present disclosure, an antenna assembly provided to generate plasma, the antenna assembly including: a feeding line to which a radio frequency (RF) signal may be applied; and a coil member branched from the feeding line at a predetermined gap and including a plurality of unit coils spaced apart from each other in a vertical direction.

According to the embodiment of the present disclosure, the plurality of unit coils of the coil member may have the same spiral shape.

According to the embodiment of the present disclosure, a first end of the plurality of unit coils may be connected to the feeding line and a second end thereof may be connected to an earthing line.

According to the embodiment of the present disclosure, the feeding line may include: a common feeding node to which a RF signal may be applied; a horizontal feeding rod coupled to the common feeding node and extending in a horizontal direction; and a vertical feeding rod coupled to the horizontal feeding rod and extending in the vertical direction and to which the plurality of unit coils may be stacked and coupled.

According to the embodiment of the present disclosure, the horizontal feeding rod may include a first horizontal feeding rod and a second horizontal feeding rod that may be branched from the common feeding node in opposite directions, the vertical feeding rod may include a first vertical feeding rod coupled to the first horizontal feeding rod and a second vertical feeding rod coupled to the second horizontal feeding rod, and the coil member may include a first coil member coupled to the first vertical feeding rod and a second coil member coupled to the second vertical feeding rod.

According to the embodiment of the present disclosure, the horizontal feeding rod may include a first horizontal feeding rod, a second horizontal feeding rod, and a third horizontal feeding rod that may be branched from the common feeding node in different directions, the vertical feeding rod may include a first vertical feeding rod coupled to the first horizontal feeding rod, a second vertical feeding rod coupled to the second horizontal feeding rod, and a third vertical feeding rod coupled to the third horizontal feeding rod, and the coil member may include a first coil member coupled to the first vertical feeding rod, a second coil member coupled to the second vertical feeding rod, and a third coil member coupled to the third vertical feeding rod.

According to another embodiment of the present disclosure, an antenna assembly provided to generate plasma may include: an inner coil member provided at a center portion at an upper side of a plasma processing chamber; and an outer coil member arranged outside the inner coil member, and including a plurality of unit coils branched from a feeding line at a predetermined gap and spaced apart from each other in a vertical direction.

According to the embodiment of the present disclosure, the inner coil member may include two inductive antennas of same structure, the two inductive antennas being connected to each other in parallel and arranged to overlap with each other.

According to the embodiment of the present disclosure, the inductive antennas include: an outer upper section arranged over a first quadrant and a second quadrant of a first layer; an inner upper section connected to the outer upper section and arranged over a third quadrant and a fourth quadrant of the first layer; an inner lower section connected to the inner upper section and arranged over a first quadrant and a second quadrant of a second layer arranged below the first layer; and an outer lower section connected to the inner lower section and arranged over a third quadrant and a fourth quadrant of the second layer.

According to the embodiment of the present disclosure, the outer coil member may include a plurality of unit coils vertically stacked at a predetermined gap.

According to the embodiment of the present disclosure, the plurality of unit coils of the outer coil member may have the same spiral shape.

According to the embodiment of the present disclosure, a first end of the plurality of unit coils may be connected to the feeding line and a second end thereof may be connected to an earthing line.

According to the embodiment of the present disclosure, the feeding line may include: a common feeding node to which a RF signal may be applied; a horizontal feeding rod coupled to the common feeding node and extending in a horizontal direction; and a vertical feeding rod coupled to the horizontal feeding rod and extending in the vertical direction and to which the plurality of unit coils may be stacked and coupled.

According to the embodiment of the present disclosure, the horizontal feeding rod may include a first horizontal feeding rod and a second horizontal feeding rod that may be branched from the common feeding node in opposite directions, the vertical feeding rod may include a first vertical feeding rod coupled to the first horizontal feeding rod and a second vertical feeding rod coupled to the second horizontal feeding rod, and the coil member may include a first coil member coupled to the first vertical feeding rod and a second coil member coupled to the second vertical feeding rod.

According to the embodiment of the present disclosure, the horizontal feeding rod may include a first horizontal feeding rod, a second horizontal feeding rod, and a third horizontal feeding rod that may be branched from the common feeding node in different directions, the vertical feeding rod may include a first vertical feeding rod coupled to the first horizontal feeding rod, a second vertical feeding rod coupled to the second horizontal feeding rod, and a third vertical feeding rod coupled to the third horizontal feeding rod, and the coil member may include a first coil member coupled to the first vertical feeding rod, a second coil member coupled to the second vertical feeding rod, and a third coil member coupled to the third vertical feeding rod.

According to the present disclosure, a plasma processing equipment may include: a plasma processing chamber configured to perform a processing with respect to a substrate; and a power supply apparatus configured to supply power to generate plasma in the plasma processing chamber, wherein the power supply apparatus may include: a radio frequency (RF) power supply part configured to generate a RF signal; an impedance matching part connected to the RF power supply part; and an antenna assembly configured to generate plasma from the RF signal, and the antenna assembly may include: an inner coil member provided at a center portion of an upper side of the plasma processing chamber; and an outer coil member arranged outside the inner coil member, and the outer coil member may include: a plurality of feeding lines to which the RF signal may be applied, and arranged at equal angles around a common feeding node; and a plurality of unit coils respectively branched from the plurality of feeding lines at predetermined gaps.

According to the embodiment of the present disclosure, the RF power supply part may include: a first RF power supply configured to generate a first RF signal; a second RF power supply configured to generate a second RF signal having a frequency same as the first RF signal or within a reference range, and the impedance matching part may include: a first matching circuit connected to the first RF power supply; and a second matching circuit connected to the second RF power supply.

The plasma processing equipment may include: a decoupling circuit connected to the impedance matching part and the antenna assembly while being located therebetween.

According to the embodiment of the present disclosure, the decoupling circuit may include: a first decoupling inductor connected to the first matching circuit and the outer coil member while being located therebetween; a second decoupling inductor connected to the second matching circuit and the inner coil member while being located therebetween and coupled to the first decoupling inductor in a mutually magnetic coupling manner; and a decoupling capacitor coupled to the first matching circuit and the second matching circuit.

The plasma processing equipment may include: a splitter configured to distribute the RF signal generated by the RF power supply part into the inner coil member and the outer coil member.

According to the present disclosure, the etching rate can be widely controlled by supplying power simultaneously to the plurality of unit coils vertically stacked at a predetermined gap from the one common feeding line.

The effect of the present disclosure is not limited to the above mention, and other effects not mentioned will be clearly understood by those skilled in the art from the description below.

### BRIEF DESCRIPTION OF THE DRAWINGS

FIG. 1 is a view showing an equivalent circuit provided by modeling a power supply system to form plasma.

FIG. 2 is a concept view showing an antenna assembly 10 and a plasma load (PL) that are expressed in circular coil shapes in an ICP plasma source.

FIGS. 3 to 5 are views showing an antenna assembly of a 2-turn coil structure and an equivalent circuit of the antenna assembly of the 2-turn coil structure.

FIGS. 6 to 8 are views showing an antenna assembly of a 4-turn coil structure and an equivalent circuit of the antenna assembly of the 4-turn coil structure.

FIGS. 9 to 11 are views showing an antenna assembly of a 6-turn coil structure and an equivalent circuit of the antenna assembly of the 6-turn coil structure.

FIGS. 12A and 12B are views showing the antenna assembly including an inner coil member and an outer coil member.

FIG. 13 is a structure of a TMI antenna that may be used as the inner coil member.

FIG. 14 is a structure of a power supply apparatus.

FIG. 15 is a view showing a plasma processing equipment to which the power supply apparatus including multiple independent power supplies and a decoupling circuit is applied.

FIG. 16 is a view showing a circuit of the power supply apparatus including the multiple independent power supplies and the decoupling circuit.

FIG. 17 is a view showing an equivalent circuit of the power supply apparatus for describing reduction of interference by the decoupling circuit.

FIG. 18 is a view showing the plasma processing equipment to which the power supply apparatus including a single power supply is applied.

FIG. 19 is a graph showing magnetic field simulation results in radial directions in a plasma chamber with respect to conditions of the number of turns of the outer coil member of the antenna assembly and a distance between the antenna assembly and plasma.

FIGS. 20A and 20B are graphs showing simulation results of magnetic field strength in response to a condition of the number of turns of the outer coil member.

### DETAILED DESCRIPTION OF THE INVENTION

Hereinbelow, exemplary embodiments of the present disclosure will be described in detail with reference to the accompanying drawings such that the present disclosure can be easily embodied by one of ordinary skill in the art to which the present disclosure belongs. The present disclosure may be changed to various embodiments and the scope and spirit of the present disclosure are not limited to the embodiments described hereinbelow.

In the following description, if it is decided that the detailed description of known function or configuration related to the present disclosure makes the subject matter of the present disclosure unclear, the detailed description is omitted, and the same reference numerals will be used throughout the drawings to refer to the elements or parts with same or similar function or operation.

Furthermore, in various embodiments, an element with same configuration will be described in a representative embodiment by using the same reference numeral, and different configuration from the representative embodiment will be described in other embodiment.

Other words used to describe the relationship between elements should be interpreted in a like fashion such as “between” versus “directly between”, “adjacent” versus “directly adjacent”, etc. It will be further understood that the terms “comprises”, “comprising”, “includes”, and/or “including”, when used herein, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Hereinbelow, according to the present disclosure, an antenna assembly and a plasma processing equipment including the same will be described.

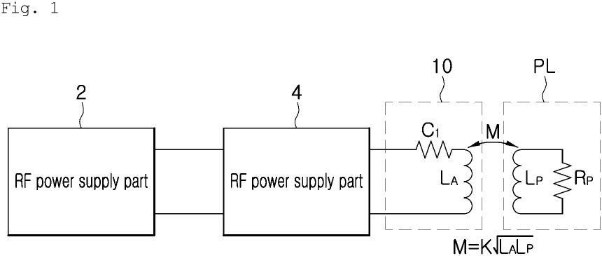

FIG. 1 is a view showing an equivalent circuit provided by modeling a power supply system to form plasma. As shown in FIG. 1, a RF power generated by a RF power supply part 2 is provided to an antenna assembly 10 via an impedance matching part 4, and the antenna assembly 10 generates an induced electric field to generate plasma. M means a mutual inductance between the antenna assembly 10 and a plasma load PL, k indicates a coupling coefficient, LA indicates an inductance of the antenna assembly 10, rA indicates a resistance value of the antenna assembly 10, LP indicates an inductance of the plasma load PL, and RP indicates a resistance value of the plasma load PL.

A full output impedance ZO including the antenna assembly 10 and the plasma load PL in a view seen from an output terminal of the impedance matching part 4 may be expressed by Equation 1 as follows.

$$\begin{matrix}{\text{Z}}_{O} = {r}_{A} + j ω {L}_{A} + \frac{{ω}^{2} {M}^{2}}{{R}_{p} + j ω {L}_{p}} \\ = \left({r}_{A} + \frac{{k}^{2} {ω}^{2} {R}_{p} {L}_{A} {L}_{P}}{{R}_{p}^{2} + {ω}^{2} {L}_{p}^{2}}\right) + j ω {L}_{A} \left(1 - \frac{{k}^{2} {ω}^{2} {L}_{p}^{2}}{{R}_{p}^{2} + {ω}^{2} {L}_{p}^{2}}\right)\end{matrix}$$

In equation 1, M means the mutual inductance between the antenna assembly 10 and the plasma load PL, k indicates the coupling coefficient, LA indicates an inductance of the antenna assembly 10, rA indicates the resistance value of the antenna assembly 10, LP indicates the inductance of the plasma load PL, RP indicates the resistance value of the plasma load PL, and ω indicates an angular frequency (ω = 2π*f0).

Herein, considering that a used frequency f0 is 13.56 Mhz, the size of the antenna assembly 10 used to a processing of a wafer of 300 mm, and the use of a high conductivity metal, according to a condition of RP « LA, LP the full output impedance ZO may be approximated as Equation 2 below.

$${Z}_{O} \approx \left({r}_{A} + \frac{{k}^{2} {R}_{P} {L}_{A}}{{L}_{P}}\right) + j ω {L}_{A} \left(1 - {k}^{2}\right)$$

Here, k is the coupling coefficient and may be expressed by an interaction equation such as Equation 3 below with respect to each inductance component.

$$k = \frac{M}{\sqrt{{L}_{A} {L}_{P}}}$$

In a real part of the Equation 2, real powers respectively consumed by the antenna assembly 10 and the plasma load PL may have an interaction as Equation 4.

$${P}_{A n t e n n a} : {P}_{P l a s m a} = {r}_{A} : \frac{{k}^{2} {R}_{P} {L}_{A}}{{L}_{P}} = {r}_{A} : \frac{{M}^{2} {R}_{P}}{{L}_{P} {}^{2}}$$

As confirmed in Equation 4, in order to increase the efficiency of power transmitted to the plasma load PL,

(i) a method of lowering real resistance rA of the antenna assembly 10,

(ii) a method of increasing the inductance LA of the antenna assembly 10, and

(iii) a method of increasing the coupling coefficient k or the mutual inductance M may be used.

However, the method (i) and the method (ii) are determined by a physical property of the antenna assembly 10, and when the inductance LA is increased for the method (ii), the real resistance rA increases and heat loss may occur. Furthermore, as shown in Equation 5, increase of a voltage Vrms applied to the antenna assembly 10 when high-frequency power P is applied to the antenna assembly 10 causes instability of the impedance matching part 4.

$${V}_{r m s} = \sqrt{P} \sqrt{\left({r}_{A} + \frac{{k}^{2} {R}_{P} {L}_{A}}{{L}_{P}}\right)} \sqrt{1 + \frac{j ω {L}_{A} \left(1 - {k}^{2}\right)}{{r}_{A} + \frac{{k}^{2} {R}_{P} {L}_{A}}{{L}_{P}}}}$$

Therefore, in order to increase the coupling coefficient k or the mutual inductance M according to the method (iii), diameters of the inductors LA and LP, a gap between the inductors LA and LP, the number of turning of inductors LA and LP should be analyzed in the 3-dimentional space, and the analysis will be described in detail.

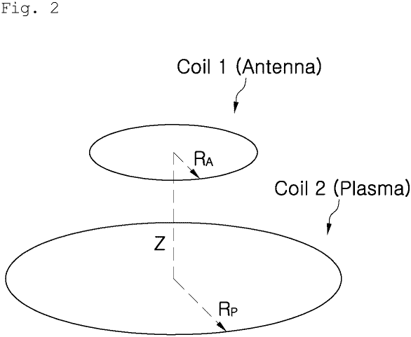

FIG. 2 is a concept view showing an antenna assembly 10 and a plasma load (PL) that are expressed in circular coil shapes in an ICP plasma source. In FIG. 2, a concept view of a circular coil shape is expressed for calculating the mutual inductance M on the antenna assembly 10 of a radius RA and the plasma load PL of a radius RP that are wound by the number of turns by NA in an ICP plasma source.

The mutual inductance M determined by the structure of the two circular coils C1 and C2 may be expressed as Equation 6 below.

$${M}_{12} = {M}_{21} = \frac{{μ}_{0}}{4 π} {∮}_{{C}_{1}} {∮}_{{C}_{2}} \frac{\text{d} \vec{{l}_{1}} ⋅ \text{d} \vec{{l}_{2}}}{\left|\vec{{r}^{′}} - \vec{r}\right|}$$

When Equation 6 is applied to relation between the antenna assembly 10 and the plasma load PL in FIG. 2, the relation may be summarized as Equation 7.

$${M}_{A P} = \frac{{μ}_{0} {N}_{A} π {R}_{A}^{2} {R}_{P}^{2}}{\sqrt{{\left({R}_{A} + {R}_{P}\right)}^{2} + {z}^{2}} \left[{\left({R}_{A} - {R}_{P}\right)}^{2} + {z}^{2}\right]}$$

The present applicant confirmed the change of the mutual inductance MAP by a radius RA that is a design element of the antenna assembly 10, a distance z between the antenna assembly 10 and the plasma load PL, the number of coils NA of the antenna from Equation 7. As a result of the confirmation, all of the radius RA that is the design element of the antenna assembly 10, the distance z between the antenna assembly 10 and the plasma load PL, the number of coils NA of the antenna are elements determining the mutual inductance, but since the elements are highly optimized the structure of the plasma chamber, the present applicant confirmed that simple numerical changes are limited in improving the radial uniformity in response to applied power.

Therefore, the present disclosure provides the antenna assembly 10 having a plurality of unit coils that is arranged in a stacked manner with a design change of an antenna and supplying power to each of the unit coils simultaneously.

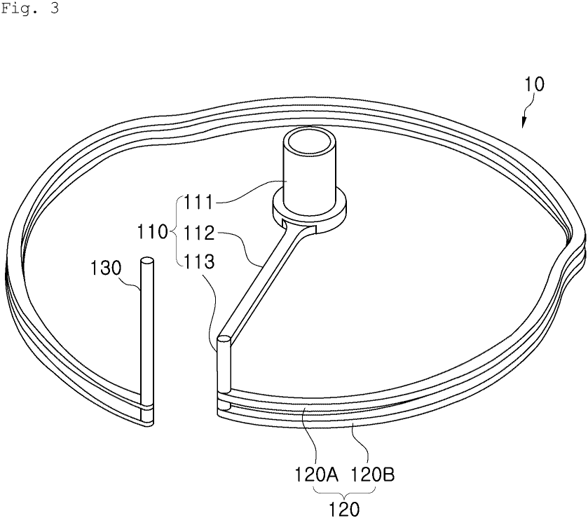

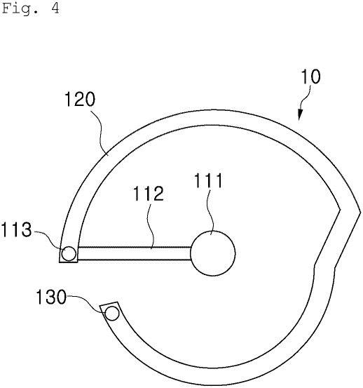

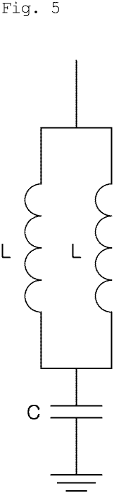

FIGS. 3 to 5 are views showing an antenna assembly 10 of a 2-turn coil structure and an equivalent circuit of the antenna assembly 10 of the 2-turn coil structure. FIG. 3 is a perspective view showing the antenna assembly 10 of the 2-turn coil structure. FIG. 4 is a top view showing the antenna assembly 10 of the 2-turn coil structure. FIG. 5 is the equivalent circuit of the antenna assembly 10 of the 2-turn coil structure.

The antenna assembly 10 configured to generate plasma according to the present disclosure includes a feeding line 110 to which a radio frequency signal is applied, and a coil member 120 including a plurality of unit coils 120A and 120B branched from the feeding line 110 at a predetermined gap and vertically stacked.

In the description, the case in which both of the two unit coils 120A and 120B are coupled to the one feeding line 110 is described as an example, but a structure in which three unit coils or more are stacked with each other is possible.

According to the present disclosure, the unit coils 120A and 120B of the coil member 120 may have the same spiral shapes.

According to the present disclosure, first ends of the unit coils 120A and 120B may be connected to the feeding line 110 and second ends thereof may be connected to an earthing line 130.

According to the present disclosure, the feeding line 110 may include a common feeding node 111 to which the RF signal is applied, a horizontal feeding rod 112 coupled to the common feeding node 111 and extending in a horizontal direction, and a vertical feeding rod 113 coupled to the horizontal feeding rod 112 and extending in a vertically direction and to which the unit coils 120A and 120B are stacked and coupled.

As shown in FIG. 3, the plurality of spiral unit coils 120A and 120B stacked with each other is connected to the one feeding line 110, and the RF signal may be simultaneously applied the unit coils 120A and 120B and power feeding may be performed. The structure of the antenna assembly 10 as the present disclosure may be referred to as a double-stacked spiral (DSS) coil structure.

FIG. 5 is an electric equivalent circuit of the antenna assembly 10 as shown in FIGS. 3 and 4. When inductance of each of the unit coils 120A and 120B is L, entire reactance X of the antenna assembly 10 may be expressed as Equation 8 below.

$$\begin{matrix}X = \frac{1}{\frac{1}{ω L} + \frac{1}{ω L}} - \frac{1}{ω C} \\ = \frac{ω L}{2} - ω C\end{matrix}$$

As shown in Equation 8, When the DSS coil structure of the simultaneous power feeding method is applied, the number of feeding lines is minimized and a low antenna inductance is secured, and simultaneously, the number of turns of coil is increased, so that the mutual inductance between the antenna assembly 10 and the plasma load PL may be increased. Therefore, the efficiency of power transferred to the plasma load PL may be increased.

Meanwhile, when a plurality of stacked spiral coils of the simultaneous power feeding method is provided, the number of turns in a limited space may be further increased.

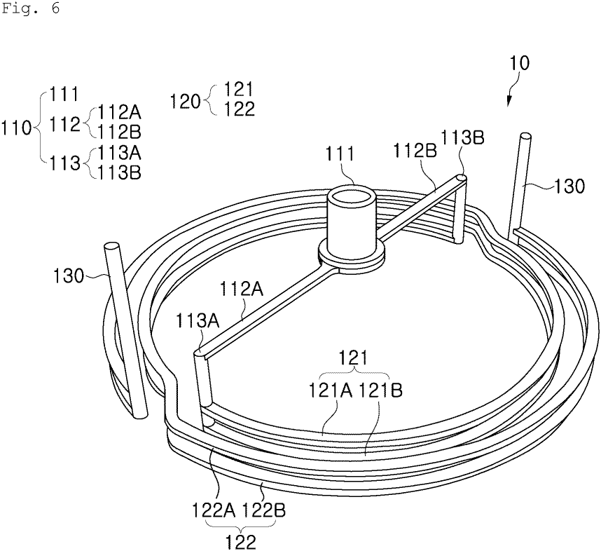

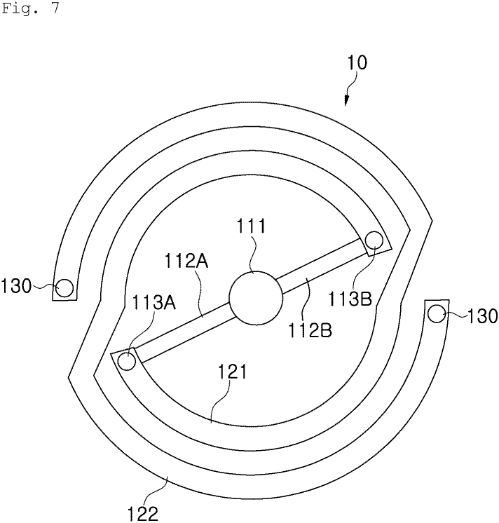

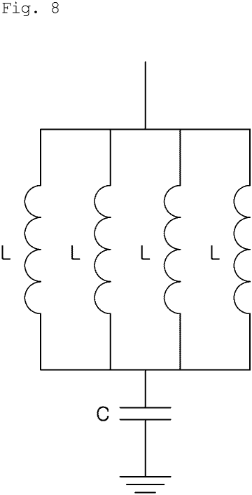

FIGS. 6 to 8 are views showing an antenna assembly of a 4-turn coil structure and an equivalent circuit of the antenna assembly of the 4-turn coil structure. FIG. 6 is a perspective view showing the antenna assembly 10 of a 4-turn coil structure. FIG. 7 is a top view showing the antenna assembly 10 of the 4-turn coil structure. FIG. 8 is an equivalent circuit of the antenna assembly 10 of the 4-turn coil structure.

As shown in FIGS. 6 and 7, the antenna assembly 10 may be configured by combining two coil members 121 and 122 having the same shapes and power inlet and outlet ports arranged opposite to each other.

According to the present disclosure, the horizontal feeding rod 112 includes a first horizontal feeding rod 112A and a second horizontal feeding rod 112B that are branched from the common feeding node 111 in opposite directions to each other, the vertical feeding rod 113 includes a first vertical feeding rod 113A coupled to the first horizontal feeding rod 112A and a second vertical feeding rod 113B coupled to the second horizontal feeding rod 112B, and the coil member 120 includes a first coil member 121 coupled to the first vertical feeding rod 113A and a second coil member 122 coupled to the second vertical feeding rod 113B.

As shown in FIGS. 6 and 7, the first horizontal feeding rod 112A and the second horizontal feeding rod 112B extend from the common feeding node 111 in the opposite directions, and the first vertical feeding rod 113A is coupled to the first horizontal feeding rod 112A and the second vertical feeding rod 113B is coupled to the second horizontal feeding rod 112B. Both of first unit coils 121A and 121B may be coupled to the first vertical feeding rod 113A while being stacked with each other at a predetermined gap, and both of second unit coils 122A and 122B may be coupled to the second vertical feeding rod 113B while being stacked with each other at a predetermined gap.

FIG. 8 is an electric equivalent circuit of the antenna assembly 10 of the 4-turn coil structure as shown in FIGS. 6 and 7. When inductance of each of the unit coils 121A, 121B, 122A, and 122B is L, the entire reactance X of the antenna assembly 10 may be expressed as Equation 9 below.

$$\begin{matrix}X = \frac{1}{\frac{1}{ω L} + \frac{1}{ω L} + \frac{1}{ω L} + \frac{1}{ω L}} - \frac{1}{ω C} \\ = \frac{ω L}{4} - ω C\end{matrix}$$

As shown in Equation 9, When the DSS coil structure of the simultaneous power feeding method is applied, the number of feeding lines is minimized and a low antenna inductance is secured, and simultaneously, the number of turns of coil is increased, so that the mutual inductance between the antenna assembly 10 and the plasma load PL may be increased. Therefore, the efficiency of power transferred to the plasma load PL may be increased.

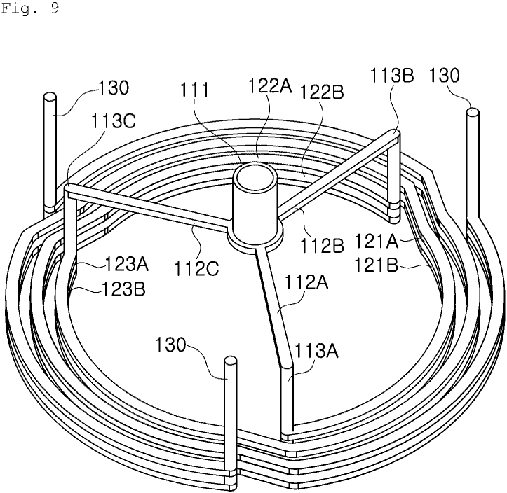

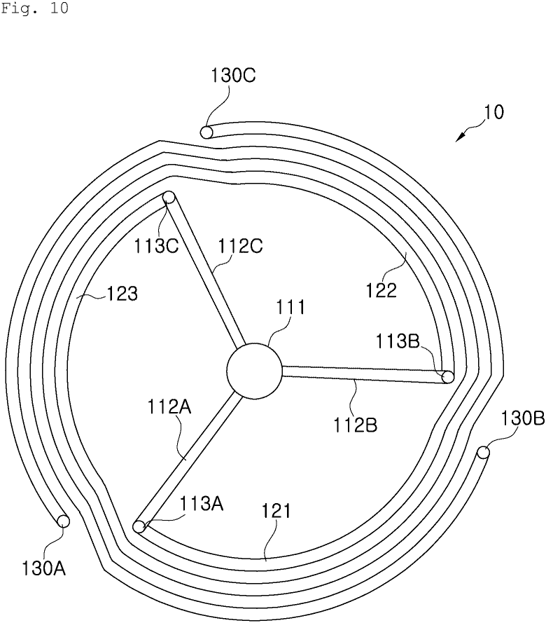

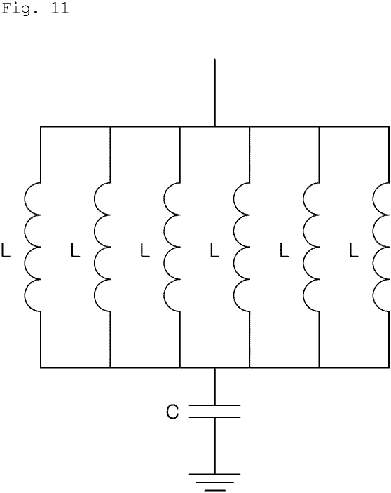

FIGS. 9 to 11 are views showing an antenna assembly of a 6-turn coil structure and an equivalent circuit of the antenna assembly of the 6-turn coil structure. FIG. 9 is a perspective view showing the antenna assembly 10 of a 6-turn coil structure. FIG. 10 is a top view showing the antenna assembly 10 of the 6-turn coil structure. FIG. 11 is an equivalent circuit of the antenna assembly 10 of the 6-turn coil structure.

As shown in FIGS. 9 and 10, the antenna assembly 10 may be configured by combining three coil members 121, 122, and 123 having the same shapes and power inlet and outlet ports arranged at gap angles of 120 degrees from each other.

According to the present disclosure, the horizontal feeding rod 112 includes the first horizontal feeding rod 112A, the second horizontal feeding rod 112B, and a third horizontal feeding rod 112C that are branched from the common feeding node 111 in different directions from each other, the vertical feeding rod 113 includes the first vertical feeding rod 113A coupled to the first horizontal feeding rod 112A, the second vertical feeding rod 113B coupled to the second horizontal feeding rod 112B, and a third vertical feeding rod 113C coupled to the third horizontal feeding rod 112C, and the coil member 120 includes the first coil member 121 coupled to the first vertical feeding rod 113A, the second coil member 122 coupled to the second vertical feeding rod 113B, and a third coil member 123 coupled to the third vertical feeding rod 113C.

As shown in FIGS. 9 and 10, the first horizontal feeding rod 112A, the second horizontal feeding rod 112B, and the third horizontal feeding rod 112C extend from the common feeding node 111 at the gap angles of 120 degrees respectively, and the first vertical feeding rod 113A is coupled to the first horizontal feeding rod 112A, the second vertical feeding rod 113B is coupled to the second horizontal feeding rod 112B, and the third vertical feeding rod 113C is coupled to the third horizontal feeding rod 112C. Both of the first unit coils 121A and 121B are coupled to the first vertical feeding rod 113A while being stacked with each other at a predetermined gap, both of the second unit coils 122A and 122B are coupled to the second vertical feeding rod 113B while being stacked with each other at a predetermined gap, and both of third unit coils 123A and 123B are coupled to the third vertical feeding rod 113C while being stacked with each other at a predetermined gap.

FIG. 11 is an electric equivalent circuit of the antenna assembly 10 of the 6-turn coil structure as shown in FIGS. 9 and 10. When inductance of each of the unit coils 121A, 121B, 122A, 122B, 123A, and 123C is L, the entire reactance X of the antenna assembly 10 may be expressed as Equation 10 below.

$$\begin{matrix}X = \frac{1}{\frac{1}{ω L} + \frac{1}{ω L} + \frac{1}{ω L} + \frac{1}{ω L} + \frac{1}{ω L} + \frac{1}{ω L}} - \frac{1}{ω C} \\ = \frac{ω L}{6} - ω C\end{matrix}$$

As shown in Equation 10, When the DSS coil structure of the simultaneous power feeding method is applied, the number of feeding lines is minimized and a low antenna inductance is secured, and simultaneously, the number of turns of coil is increased, so that the mutual inductance between the antenna assembly 10 and the plasma load PL may be increased. Therefore, the efficiency of power transferred to the plasma load PL may be increased.

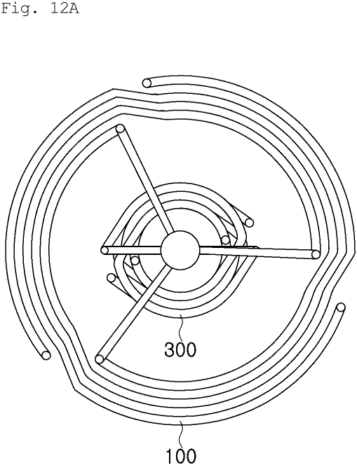

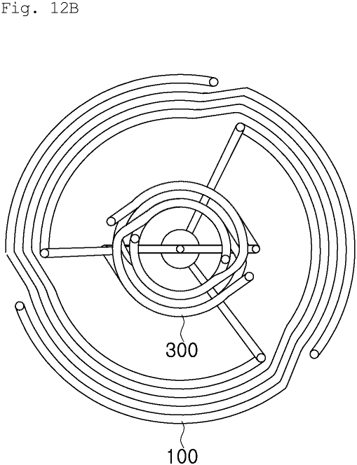

FIG. 12 is a view showing the antenna assembly 10 including an inner coil member 300 and an outer coil member 100. FIG. 12A is a top view of the antenna assembly 10, and FIG. 12B is a bottom view of the antenna assembly 10. In an etching device using plasma, in order to achieve uniform etching rate with respect to the entire area of a wafer, the antenna assembly 10 including the inner coil member 300 and the outer coil member 100 may be used. In general, since the etching rate in an outer portion of the wafer is lowered than the etching rate in a center portion, the etching rate of the outer portion needs to be precisely controlled, and in order to control the etching rate precisely, the inner coil member 300 and the outer coil member 100 may be provided. Comparing the outer coil member to the inner coil member 300, since change of the etching rate of the outer portion of the wafer is less even in adjustment of a current rate, the outer coil member 100 needs to be configured to control the etching rate more broadly.

According to the present disclosure, the antenna assembly 10 may include the inner coil member 300 provided at an upper center portion of the plasma processing chamber, and the outer coil member 100 arranged outside the inner coil member 300 and including a plurality of unit coils branched from the feeding line at a predetermined gap and vertically stacked. As described above, as the outer coil member 100 of the form consisting of the stacked unit coils is applied, extensive control of the etching rate with respect to the outer portion of the wafer may be performed.

The unit coils of the outer coil member 100 may be shaped in the same spiral shapes.

Here, a first end of each of the unit coils may be connected to the feeding line 110 and a second end thereof may be connected to the earthing line 130.

According to the present disclosure, the feeding line 110 of the outer coil member 100 may include the common feeding node 111 to which the RF signal is applied, the horizontal feeding rod 112 coupled to the common feeding node 111 and extending in the horizontal direction, and the vertical feeding rod 113 coupled to the horizontal feeding rod 112 and extending in the vertically direction and to which the unit coils 120A and 120B are stacked and coupled.

As shown in FIG. 3, the plurality of spiral unit coils 120A and 120B stacked with each other is connected to the one feeding line 110, and the RF signal may be simultaneously applied the unit coils 120A and 120B and power feeding may be performed.

According to the present disclosure, the horizontal feeding rod 112 of the outer coil member 100 may include the first horizontal feeding rod 112A and the second horizontal feeding rod 112B that are branched from the common feeding node 111 in opposite directions, the vertical feeding rod 113 may include the first vertical feeding rod 113A coupled to the first horizontal feeding rod 112A and the second vertical feeding rod 113B coupled to the second horizontal feeding rod 112B, and the coil member 120 may include the first coil member 121 coupled to the first vertical feeding rod 113A and the second coil member 122 coupled to the second vertical feeding rod 113B.

As shown in FIGS. 6 and 7, the first horizontal feeding rod 112A and the second horizontal feeding rod 112B extend from the common feeding node 111 in the opposite directions, and the first vertical feeding rod 113A is coupled to the first horizontal feeding rod 112A and the second vertical feeding rod 113B is coupled to the second horizontal feeding rod 112B. Both of first unit coils 121A and 121B may be coupled to the first vertical feeding rod 113A while being stacked with each other at a predetermined gap, and both of second unit coils 122A and 122B may be coupled to the second vertical feeding rod 113B while being stacked with each other at a predetermined gap.

According to the present disclosure, the horizontal feeding rod 112 includes the first horizontal feeding rod 112A, the second horizontal feeding rod 112B, and a third horizontal feeding rod 112C that are branched from the common feeding node 111 in different directions from each other, the vertical feeding rod 113 includes the first vertical feeding rod 113A coupled to the first horizontal feeding rod 112A, the second vertical feeding rod 113B coupled to the second horizontal feeding rod 112B, and a third vertical feeding rod 113C coupled to the third horizontal feeding rod 112C, and the coil member 120 includes the first coil member 121 coupled to the first vertical feeding rod 113A, the second coil member 122 coupled to the second vertical feeding rod 113B, and a third coil member 123 coupled to the third vertical feeding rod 113C.

As shown in FIGS. 9 and 10, the first horizontal feeding rod 112A, the second horizontal feeding rod 112B, and the third horizontal feeding rod 112C extend from the common feeding node 111 at the gap angles of 120 degrees respectively, and the first vertical feeding rod 113A is coupled to the first horizontal feeding rod 112A, the second vertical feeding rod 113B is coupled to the second horizontal feeding rod 112B, and the third vertical feeding rod 113C is coupled to the third horizontal feeding rod 112C. Both of the first unit coils 121A and 121B are coupled to the first vertical feeding rod 113A while being stacked with each other at a predetermined gap, both of the second unit coils 122A and 122B are coupled to the second vertical feeding rod 113B while being stacked with each other at a predetermined gap, and both of third unit coils 123A and 123B are coupled to the third vertical feeding rod 113C while being stacked with each other at a predetermined gap.

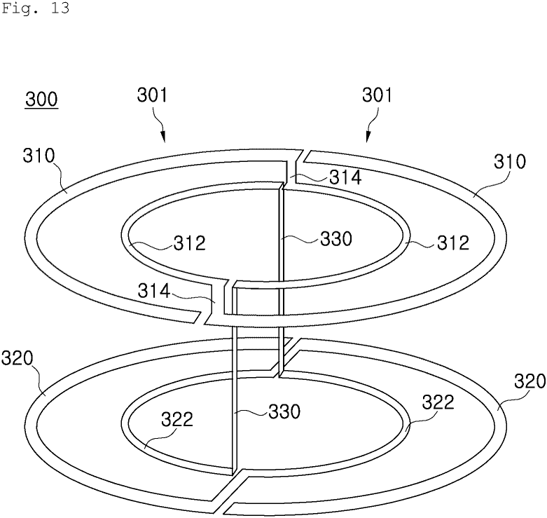

In the inner coil member 300, a twisted multi-layer inductor (TMI) antenna as shown in FIG. 13 may be applied. FIG. 13 is a structure of a TMI antenna that may be used as the inner coil member. The structure of the TMI antenna was described in Korean Patent No. 10-1125624.

According to the present disclosure, the inner coil member 300 may include two inductive antennas 301 of the same structure, and the two inductive antennas 301 are connected to each other in parallel and arranged overlapped with each other. Each of the inductive antennas 301 includes an outer upper section 310 arranged over a first quadrant and a second quadrant of a first layer, an inner upper section 312 connected to the outer upper section 310 and arranged over a third quadrant and a fourth quadrant of the first layer, an inner lower section 322 connected to the inner upper section 312 and arranged over a first quadrant and a second quadrant of a second layer arranged below the first layer, and an outer lower section 320 connected to the inner lower section 322 and arranged over a third quadrant and a fourth quadrant of the second layer. A first end of the outer upper section 310 is connected to the feeding line, and a second end of the outer lower section 320 is connected to the earthing line.

Meanwhile, the inner coil member 300 may include a plurality of unit coils vertically stacked at a predetermined gap like the outer coil member 100.

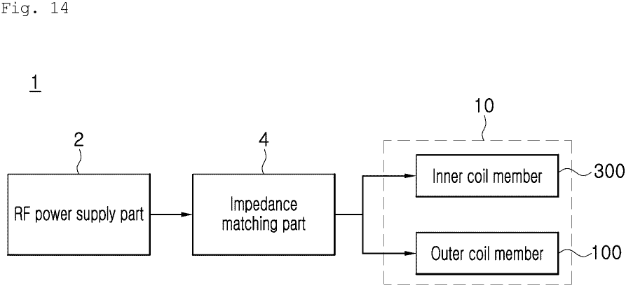

FIG. 14 is a structure of a power supply apparatus 1.

According to the present disclosure, the power supply apparatus 1 includes the RF power supply part 2 generating a RF signal, the impedance matching part 4 connected to the RF power supply part 2, and the antenna assembly 10 generating plasma from the RF signal. The antenna assembly 10 may include the inner coil member 300 provided at the upper center portion of the plasma processing chamber 40, and the outer coil member 100 arranged outside the inner coil member 300. The outer coil member 100 may include a plurality of feeding lines 110 to which the RF signal is applied and arranged around the common feeding node at equal angles, and a plurality of unit coils respectively branched from the feeding lines 110 at predetermined gaps and vertically stacked with each other.

The antenna assembly 10 may include the outer coil member 100 including the plurality of unit coils vertically stacked with each other at the predetermined gaps.

In an etching device using plasma, in order to achieve uniform etching rate with respect to the entire area of a wafer, the antenna assembly 10 including the inner coil member 300 and the outer coil member 100 may be used. In general, since the etching rate in an outer portion of the wafer is lowered than the etching rate in a center portion, the etching rate of the outer portion needs to be precisely controlled, and in order to control the etching rate precisely, the inner coil member 300 and the outer coil member 100 may be provided. Comparing the outer coil member to the inner coil member 300, since change of the etching rate of the outer portion of the wafer is less even in adjustment of a current rate, the outer coil member 100 needs to be configured to control the etching rate more broadly.

According to the present disclosure, the antenna assembly 10 may include the inner coil member 300 provided at the upper center portion of the plasma processing chamber 40, and the outer coil member 100 arranged outside the inner coil member 300 and including the plurality of unit coils vertically stacked at a predetermined gap. As described above, as the outer coil member 100 of the form consisting of the stacked unit coils is applied, extensive control of the etching rate with respect to the outer portion of the wafer may be performed.

The unit coils of the outer coil member 100 may be shaped in the same spiral shapes.

Here, a first end of each of the unit coils may be connected to the feeding line 110 and a second end thereof may be connected to the earthing line 130.

According to the present disclosure, the feeding line 110 of the outer coil member 100 may include the common feeding node 111 to which the RF signal is applied, the horizontal feeding rod 112 coupled to the common feeding node 111 and extending in the horizontal direction, and the vertical feeding rod 113 coupled to the horizontal feeding rod 112 and extending in the vertically direction and to which the unit coils 120A and 120B are stacked and coupled.

As shown in FIG. 3, the plurality of spiral unit coils 120A and 120B stacked with each other is connected to the one feeding line 110, and the RF signal may be simultaneously applied the unit coils 120A and 120B and power feeding may be performed.

According to the present disclosure, as shown in FIGS. 6 and 7, the horizontal feeding rod 112 of the outer coil member 100 includes the first horizontal feeding rod 112A and the second horizontal feeding rod 112B that are branched from the common feeding node 111 in opposite directions to each other, the vertical feeding rod 113 includes the first vertical feeding rod 113A coupled to the first horizontal feeding rod 112A and the second vertical feeding rod 113B coupled to the second horizontal feeding rod 112B, and the coil member 120 includes the first coil member 121 coupled to the first vertical feeding rod 113A and the second coil member 122 coupled to the second vertical feeding rod 113B.

As shown in FIGS. 6 and 7, the first horizontal feeding rod 112A and the second horizontal feeding rod 112B extend from the common feeding node 111 in the opposite directions, and the first vertical feeding rod 113A is coupled to the first horizontal feeding rod 112A and the second vertical feeding rod 113B is coupled to the second horizontal feeding rod 112B. Both of first unit coils 121A and 121B may be coupled to the first vertical feeding rod 113A while being stacked with each other at a predetermined gap, and both of second unit coils 122A and 122B may be coupled to the second vertical feeding rod 113B while being stacked with each other at a predetermined gap.

According to the present disclosure, as shown in FIGS. 9 and 10, the horizontal feeding rod 112 includes the first horizontal feeding rod 112A, the second horizontal feeding rod 112B, and the third horizontal feeding rod 112C that are branched from the common feeding node 111 in different directions from each other, the vertical feeding rod 113 includes the first vertical feeding rod 113A coupled to the first horizontal feeding rod 112A, the second vertical feeding rod 113B coupled to the second horizontal feeding rod 112B, and the third vertical feeding rod 113C coupled to the third horizontal feeding rod 112C, and the coil member 120 includes the first coil member 121 coupled to the first vertical feeding rod 113A, the second coil member 122 coupled to the second vertical feeding rod 113B, and the third coil member 123 coupled to the third vertical feeding rod 113C.

As shown in FIGS. 9 and 10, the first horizontal feeding rod 112A, the second horizontal feeding rod 112B, and the third horizontal feeding rod 112C extend from the common feeding node 111 at the gap angles of 120 degrees respectively, and the first vertical feeding rod 113A is coupled to the first horizontal feeding rod 112A, the second vertical feeding rod 113B is coupled to the second horizontal feeding rod 112B, and the third vertical feeding rod 113C is coupled to the third horizontal feeding rod 112C. Both of the first unit coils 121A and 121B are coupled to the first vertical feeding rod 113A while being stacked with each other at a predetermined gap, both of the second unit coils 122A and 122B are coupled to the second vertical feeding rod 113B while being stacked with each other at a predetermined gap, and both of third unit coils 123A and 123B are coupled to the third vertical feeding rod 113C while being stacked with each other at a predetermined gap.

In the inner coil member 300, a twisted multi-layer inductor (TMI) antenna as shown in FIG. 13 may be applied. FIG. 13 is a structure of a TMI antenna that may be used as the inner coil member. The structure of the TMI antenna was described in detail in Korean Patent No. 10-1125624.

According to the present disclosure, the inner coil member 300 may include two inductive antennas 301 of the same structure, and the two inductive antennas 301 are connected to each other in parallel and arranged overlapped with each other. Each of the inductive antennas 301 includes an outer upper section 310 arranged over a first quadrant and a second quadrant of a first layer, an inner upper section 312 connected to the outer upper section 310 and arranged over a third quadrant and a fourth quadrant of the first layer, an inner lower section 322 connected to the inner upper section 312 and arranged over a first quadrant and a second quadrant of a second layer arranged below the first layer, and an outer lower section 320 connected to the inner lower section 322 and arranged over a third quadrant and a fourth quadrant of the second layer. A first end of the outer upper section 310 is connected to the feeding line, and a second end of the outer lower section 320 is connected to the earthing line.

Meanwhile, the inner coil member 300 may include a plurality of unit coils vertically stacked at a predetermined gap like the outer coil member 100.

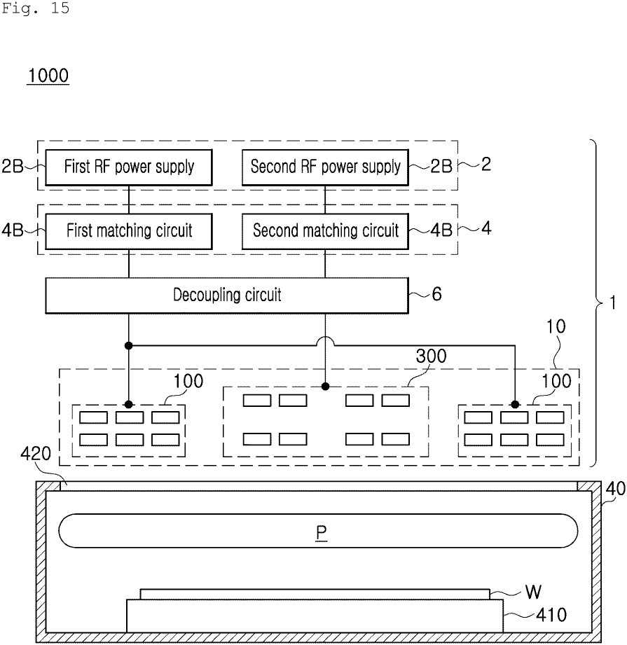

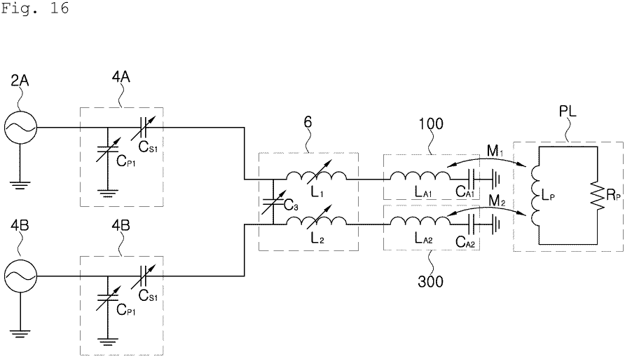

FIG. 15 is a view showing a plasma processing equipment 1000 to which the power supply apparatus 1 including multiple independent power supplies and a decoupling circuit is applied. FIG. 16 is a view showing a circuit of the power supply apparatus 1 including the multiple independent power supplies and the decoupling circuit.

The plasma processing equipment 1000 performs a process while changing process gas, temperature, pressure, etc. in response to a process condition, and recently, as a high-level stacked structure is required, a plasma state change occurs for each process stage. The plasma state change causes impedance change in the plasma processing chamber and impedance mismatching may occur in response to the impedance change. Therefore, the power supply apparatus 1 performs impedance matching to minimize the impedance mismatching, and specifically, a rapid impedance matching is required to increase the efficiency of a process.

In the power supply apparatus 1 according to the embodiment of the present disclosure, the RF power supply part 2 includes a first RF power supply 2A generating a first RF signal, a second RF power supply 2B generating a second RF signal having a frequency same as a frequency of the first RF signal or within a reference range. The impedance matching part 4 includes a first matching circuit 4A connected to the first RF power supply 2A, and a second matching circuit 4B connected to the second RF power supply 2B.

When the independent power supply apparatus 1 arranged in parallel is provided as shown FIGS. 15 and 16, entire power is distributed and supplied to the plasma load PL, so that a region of voltage and current movement of each matching circuit 4A, 4B may be reduced and change of impedance of each matching circuit 4A, 4B may be minimized. As the movement region and impedance change is reduced, faster impedance matching is possible.

Meanwhile, the power supply apparatus 1 may include a decoupling circuit 6 connected to the impedance matching part 4 and the antenna assembly 10 while being located between the impedance matching part 4 and the antenna assembly 10.

The decoupling circuit 6 includes a first decoupling inductor L1 connected to the first matching circuit 4A and the outer coil member 100 while being located between the first matching circuit 4A and the outer coil member 100, a second decoupling inductor L2 connected to the second matching circuit 4B and the inner coil member 300 while being located between the second matching circuit 4B and the inner coil member 300 and mutually magnetically coupled to the first decoupling inductor L1, and a decoupling capacitor C3 connected to the first matching circuit 4A and the second matching circuit 4B while being located between the first matching circuit 4A and the second matching circuit 4B.

Meanwhile, as shown in FIG. 15, the antenna assembly 10 generates the plasma P in the inside space of the plasma processing chamber 40, and a process (etching process) for the wafer W loaded on an upper portion of an electrostatic chuck 410 is performed by the plasma P. Meanwhile, the window 420 consisting of an dielectric material is provided at the upper portion of the plasma processing chamber 40 to divide a chamber region and an antenna region from each other.

Referring to FIG. 16, the first decoupling inductor L1 is connected to the first matching circuit 4A, which is connected to the first RF power supply 2A and includes variable capacitors CP1 and CS1, and the outer coil member 100 while being located between the first matching circuit 4A and the outer coil member 100, and the second decoupling inductor L2 is connected to the second matching circuit 4B, which is connected to the second RF power supply 2B and includes variable capacitors CP2 and CS2, and the inner coil member 300 while being located between the second matching circuit 4B and the inner coil member 300. In order to tune impedance of the decoupling circuit 6, the decoupling capacitor C3 may be connected to the first matching circuit 4A and the second matching circuit 4B.

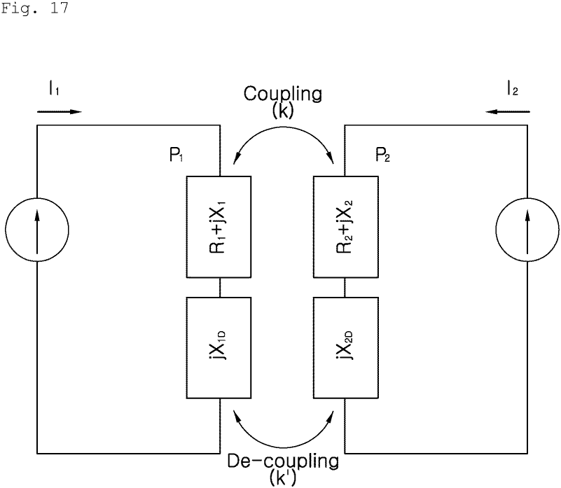

The decoupling circuit 6 may be designed to block crosstalk between the independent power supply circuits. The principle of decoupling performed by the decoupling circuit 6 may be described with reference to the equivalent circuit shown in FIG. 17.

FIG. 17 is a view showing an equivalent circuit of the power supply apparatus 1 for describing the removal of interference by the decoupling part.

In FIG. 17, R1 and X1 indicate a resistor and a reactance component of the power transfer circuit (the first matching circuit 4A, the outer coil member 100) connected to the first RF power supply 2A, R2 and X2 indicate a resistor and a reactance component of the power transfer circuit (the second matching circuit 4B, the inner coil member 300) connected to the second RF power supply 2B, X1D indicates reactance added to the power transfer circuit connected to the first RF power supply 2A due to adding of the decoupling circuit 6, and X2D indicates reactance added to the power transfer circuit connected to the second RF power supply 2B due to adding of the decoupling circuit 6.

At this time, in the equivalent circuit of the power supply apparatus 1, a load of the power transfer circuit connected to the first RF power supply 2A and power P1 applied to all decoupling reactive element are expressed as Equation 11 below.

$${P}_{1} = {I}_{1}^{2} {R}_{1} + j {I}_{1}^{2} {X}_{1} + j {I}_{1}^{2} {X}_{1 D} + j k {I}_{2}^{2} {X}_{2} + j {k}^{′} {I}_{2}^{2} {X}_{2 D}$$

Here, the decoupling reactive element of the added decoupling circuit 6 is designed to satisfy a condition as shown in Equation 12 below.

$$- \frac{k}{{k}^{′}} = \frac{{X}_{2 \text{} D}}{{X}_{2}} = \frac{{X}_{1 \text{} D}}{{X}_{1}}$$

In Equations 11 and 12, R1 and X1 indicate impedance components (resistor, reactance) in an equivalent circuit of a first power supply part applied to a first RF signal, R2 and X2 indicate impedance components (resistor, reactance) in an equivalent circuit of a second power supply part to which the second RF signal is applied, k indicates a coupling coefficient between the equivalent circuit of the first power supply part and the equivalent circuit of the second power supply part 20, which is generated by coupling between the power transfer circuits (antenna), k′ is a coupling coefficient between reactance added by the decoupling circuit 6 in the equivalent circuit of the first power supply part and reactance added by the decoupling circuit 6 in the equivalent circuit of the second power supply part, which is generated by coupling between inductive reactive elements (the first decoupling inductor L1 and the second decoupling inductor L2) in the decoupling circuit 6, X1D is reactance added by the decoupling circuit 6 in the equivalent circuit of the first power supply part, and X2D is reactance added by the decoupling circuit 6 in the equivalent circuit of the second power supply part.

As shown in FIG. 16, when the decoupling circuit 6 consisting of the reactive element is added, a low coupling coefficient exists in a use frequency region. The coupling coefficient equal to or less than a predetermined level may be obtained in the same frequency as the use frequency or a close frequency within a 5% range.

Meanwhile, power may be supplied to the inner coil member 300 and the outer coil member 100 by a single power supply.

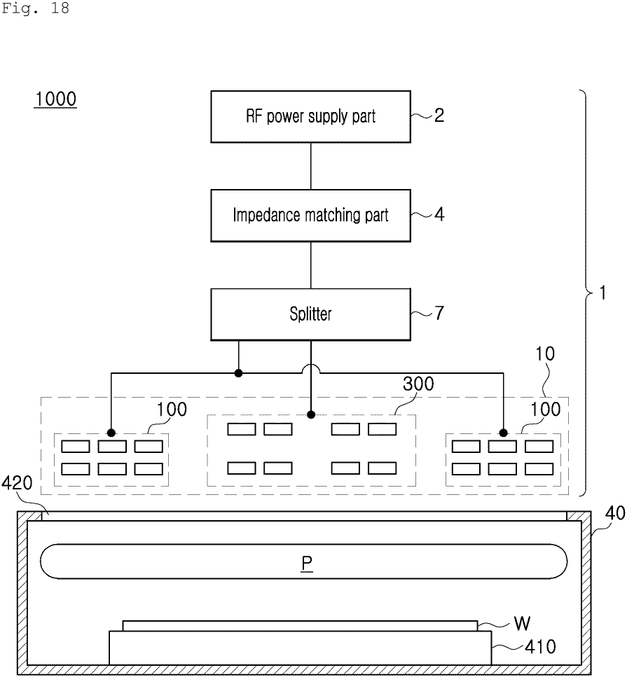

FIG. 18 is a view showing the plasma processing equipment 1000 to which the power supply apparatus 1 including a single power supply is applied.

According to the present disclosure, the plasma processing equipment 1000 includes the plasma processing chamber 40 performing a process with respect to the wafer W, and the power supply apparatus 1 supplying power to generate plasma in the plasma processing chamber 40.

According to the present disclosure, the power supply apparatus 1 of the plasma processing equipment 1000 includes the RF power supply part 2 generating a RF signal, the impedance matching part 4 connected to the RF power supply part 2, and the antenna assembly 10 generating plasma from the RF signal. The antenna assembly 10 may include the inner coil member 300 provided at the upper center portion of the plasma processing chamber 40, and the outer coil member 100 arranged outside the inner coil member 300 and including the plurality of unit coils vertically stacked at a predetermined gap.

Meanwhile, the power supply apparatus 1 may include a splitter 7 distributing the RF signal generated by the RF power supply part 2 into the inner coil member 300 and the outer coil member 100. As shown in FIG. 18, the RF signal generated by the RF power supply part 2 is supplied to the splitter 7 via the impedance matching part 4. The splitter 7 may distribute the supplied power into the inner coil member 300 and the outer coil member 100. The splitter 7 may consist of reactance elements such as an inductor or a capacitor. The splitter 7 is connected to both of the inner coil member 300 and the outer coil member 100, and the inner coil member 300 and the outer coil member 100 may generate the plasma P from the RF signal distributed by the splitter 7.

Meanwhile, as shown in FIG. 18, the antenna assembly 10 generates the plasma P in the inside space of the plasma processing chamber 40, and a process (etching process) for the wafer W loaded on the upper portion of an electrostatic chuck 410 is performed by the plasma P. Meanwhile, the window 420 consisting of an dielectric material is provided at the upper portion of the plasma processing chamber 40 to divide a chamber region and an antenna region from each other.

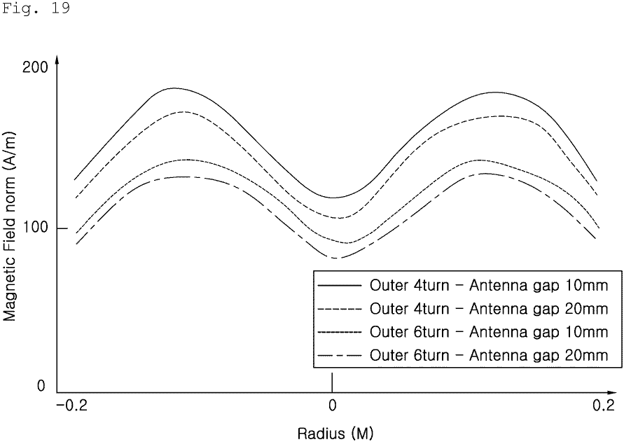

FIG. 19 is a graph showing magnetic field simulation results in radial directions in a plasma chamber with respect to conditions of the number of turns of the outer coil member 100 of the antenna assembly 10 and a distance between the antenna assembly 10 and plasma.

In order to identify an effect by the number of turns of the outer coil member of the antenna assembly and an effect by the distance between the antenna assembly and the plasma simultaneously, simulations for four cases were performed. As the condition of the number of turns of the outer coil member, comparison of a case of the 4-turn same as the number of turns of the inner coil member and a case of 6-turn was performed. Furthermore, in the two condition of the number of turns of the outer coil member, a gap between upper and lower coils is changed to 10 mm and 20 mm, and change of a magnetic field in response to change of the distance between the upper coil and the plasma was identified. For the four conditions, the density of the plasma in the chamber is preset to 1014 m-3 equally for the four conditions, and a power feeding condition is preset such that sinusoidal current with a frequency of 13.56 MHz is applied at 50A and 100A equally to the inner coil member 300 and the outer coil member 100.

When the distance between the antenna assembly 10 and the plasma is reduced from 20 mm to 10 mm, in both of the two conditions of 4-turn and 6-turn of the outer coil member 100, an increase of magnetic field in the chamber of about 10 A/m is identified. The above result shows clearly an increase effect of the mutual inductance by reduction of the distance between the antenna assembly 10 and the plasma.

When the number of turns of the outer coil member 100 is increased from 4-turn to 6-turn, in both cases that the distance between the antenna assembly 10 and the plasma is 10 mm and 20 mm, an overall magnetic field increase of 40 A/m was shown. Furthermore, in a change of the distribution of the magnetic field in a radial direction, it is identified that a width of magnetic field was the largest in a portion of 0.14 m that is an outer portion of a wafer of 300 mm.

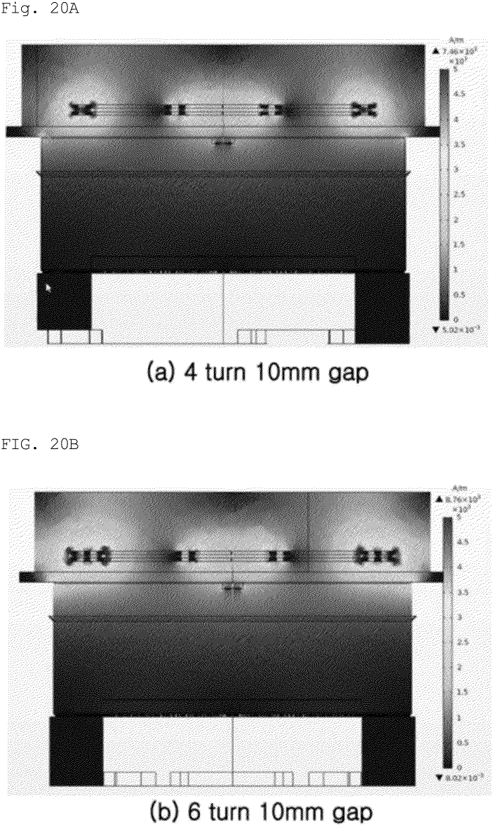

FIGS. 20A and 12B are graphs showing simulation results of magnetic field strength in response to a condition of the number of turns of the outer coil member. FIG. 20A is a view showing the magnetic field strength distribution in a case in which the number of turns of the outer coil member 100 4 turns and the distance between the antenna assembly 10 and the plasma is 10 mm. FIG. 20B is a view showing the magnetic field strength distribution in a case in which the number of turns of the outer coil member 100 is 6 turns and the distance between the antenna assembly 10 and the plasma is 10 mm.

When the number of turns of the outer coil member 100 is increased, the distribution of the magnetic field around the inner coil member 300 is maintained in the similar level before and after, but it is identified that the distribution of the magnetic field around the outer coil member 100 is significantly increased in the 6-turn condition, and the magnetic field strength in the plasma chamber is increased together. As described above, increase of the magnetic field strength in the wafer outer region shows when the number of turns of the outer coil member is increased by using the simultaneous power feeding method, improvement of distribution of the radial etching rate.

Although the preferred embodiments of the present disclosure have been disclosed for illustrative purposes, those skilled in the art will appreciate that various modifications, additions and substitutions are possible, without departing from the scope and spirit of the invention as disclosed in the accompanying claims. Since the present disclosure may be embodied in other specific forms without changing the technical sprit or essential features, those skilled in the art to which the present disclosure belongs should understand that the embodiments described above are exemplary and not intended to limit the present disclosure.

The scope of the present disclosure will be defined by the accompanying claims rather than by the detailed description, and those skilled in the art should understand that various modifications, additions and substitutions derived from the meaning and scope of the present disclosure and the equivalent concept thereof are included in the scope of the present disclosure.

What is claimed is:

1. An antenna assembly provided to generate plasma, the antenna assembly comprising:
a feeding line to which a radio frequency (RF) signal is applied; and
a coil member branched from the feeding line at a predetermined gap and comprising a plurality of unit coils spaced apart from each other in a vertical direction.

2. The antenna assembly of claim 1, wherein the plurality of unit coils of the coil member has a same spiral shape.

3. The antenna assembly of claim 2, wherein a first end of the plurality of unit coils is connected to the feeding line and a second end thereof is connected to an earthing line.

4. The antenna assembly of claim 1, wherein the feeding line comprises:
a common feeding node to which a RF signal is applied;
a horizontal feeding rod coupled to the common feeding node and extending in a horizontal direction; and
a vertical feeding rod coupled to the horizontal feeding rod and extending in the vertical direction and to which the plurality of unit coils is stacked and coupled.

5. The antenna assembly of claim 4, wherein the horizontal feeding rod comprises a first horizontal feeding rod and a second horizontal feeding rod that are branched from the common feeding node in opposite directions,
the vertical feeding rod comprises a first vertical feeding rod coupled to the first horizontal feeding rod and a second vertical feeding rod coupled to the second horizontal feeding rod, and
the coil member comprises a first coil member coupled to the first vertical feeding rod and a second coil member coupled to the second vertical feeding rod.

6. The antenna assembly of claim 4, wherein the horizontal feeding rod comprises a first horizontal feeding rod, a second horizontal feeding rod, and a third horizontal feeding rod that are branched from the common feeding node in different directions,
the vertical feeding rod comprises a first vertical feeding rod coupled to the first horizontal feeding rod, a second vertical feeding rod coupled to the second horizontal feeding rod, and a third vertical feeding rod coupled to the third horizontal feeding rod, and
the coil member comprises a first coil member coupled to the first vertical feeding rod, a second coil member coupled to the second vertical feeding rod, and a third coil member coupled to the third vertical feeding rod.

7. An antenna assembly provided to generate plasma, the antenna assembly comprising:
an inner coil member provided at a center portion at an upper side of a plasma processing chamber; and
an outer coil member arranged outside the inner coil member, and comprising a plurality of unit coils branched from a feeding line at a predetermined gap and spaced apart from each other in a vertical direction.

8. The antenna assembly of claim 7, wherein the inner coil member comprises two inductive antennas of same structure, the two inductive antennas being connected to each other in parallel and arranged to overlap with each other.

9. The antenna assembly of claim 8, wherein the inductive antennas comprise:
an outer upper section arranged over a first quadrant and a second quadrant of a first layer;
an inner upper section connected to the outer upper section and arranged over a third quadrant and a fourth quadrant of the first layer;
an inner lower section connected to the inner upper section and arranged over a first quadrant and a second quadrant of a second layer arranged below the first layer; and
an outer lower section connected to the inner lower section and arranged over a third quadrant and a fourth quadrant of the second layer.

10. The antenna assembly of claim 7, wherein the outer coil member comprises a plurality of unit coils vertically stacked at a predetermined gap.

11. The antenna assembly of claim 7, wherein the plurality of unit coils of the outer coil member has a same spiral shape.

12. The antenna assembly of claim 7, wherein a first end of the plurality of unit coils is connected to the feeding line and a second end thereof is connected to an earthing line.

13. The antenna assembly of claim 12, wherein the feeding line comprises:
a common feeding node to which a radio frequency (RF) signal is applied;
a horizontal feeding rod coupled to the common feeding node and extending in a horizontal direction; and
a vertical feeding rod coupled to the horizontal feeding rod and extending in the vertical direction and to which the plurality of unit coils is stacked and coupled.

14. The antenna assembly of claim 13, wherein the horizontal feeding rod comprises a first horizontal feeding rod and a second horizontal feeding rod that are branched from the common feeding node in opposite directions,
the vertical feeding rod comprises a first vertical feeding rod coupled to the first horizontal feeding rod and a second vertical feeding rod coupled to the second horizontal feeding rod, and
the coil member comprises a first coil member coupled to the first vertical feeding rod and a second coil member coupled to the second vertical feeding rod.

15. The antenna assembly of claim 13, wherein the horizontal feeding rod comprises a first horizontal feeding rod, a second horizontal feeding rod, and a third horizontal feeding rod that are branched from the common feeding node in different directions,
the vertical feeding rod comprises a first vertical feeding rod coupled to the first horizontal feeding rod, a second vertical feeding rod coupled to the second horizontal feeding rod, and a third vertical feeding rod coupled to the third horizontal feeding rod, and
the coil member comprises a first coil member coupled to the first vertical feeding rod, a second coil member coupled to the second vertical feeding rod, and a third coil member coupled to the third vertical feeding rod.

16. A plasma processing equipment comprising:
a plasma processing chamber configured to perform a process treatment with respect to a substrate; and
a power supply apparatus configured to supply power to generate plasma in the plasma processing chamber,
wherein the power supply apparatus comprises:
a radio frequency (RF) power supply part configured to generate a RF signal;
an impedance matching part connected to the RF power supply part; and
an antenna assembly configured to generate plasma from the RF signal, and
the antenna assembly comprises:
an inner coil member provided at a center portion of an upper side of the plasma processing chamber; and
an outer coil member arranged outside the inner coil member, and
the outer coil member comprises:
a plurality of feeding lines to which the RF signal is applied, and arranged at equal angles around a common feeding node; and
a plurality of unit coils respectively branched from the plurality of feeding lines at predetermined gaps.

17. The plasma processing equipment of claim 16, wherein the RF power supply part comprises:
a first RF power supply configured to generate a first RF signal;
a second RF power supply configured to generate a second RF signal having a frequency same as the first RF signal or within a reference range, and
the impedance matching part comprises:
a first matching circuit connected to the first RF power supply; and
a second matching circuit connected to the second RF power supply.

18. The plasma processing equipment of claim 17, further comprising:
a decoupling circuit connected to the impedance matching part and the antenna assembly while being located therebetween.

19. The plasma processing equipment of claim 18, wherein the decoupling circuit comprises:
a first decoupling inductor connected to the first matching circuit and the outer coil member while being located therebetween;
a second decoupling inductor connected to the second matching circuit and the inner coil member while being located therebetween and coupled to the first decoupling inductor in a mutually magnetic coupling manner; and
a decoupling capacitor coupled to the first matching circuit and the second matching circuit.

20. The plasma processing equipment of claim 16, further comprising:
a splitter configured to distribute the RF signal generated by the RF power supply part into the inner coil member and the outer coil member.
